(19) United States
(12) Patent Application Publication
(10) Pub. No.: US 2025/0202482 A1
(43) Pub. Date: Jun. 19, 2025

(54) BROADBAND ABSORPTIVE TERMINATION IN DIODE SWITCHES

(71) Applicant: MACOM Technology Solutions Holdings, Inc., Lowell, MA (US)

(72) Inventor: Andrzej Rozbicki, San Jose, CA (US)

(21) Appl. No.: 18/538,580

(22) Filed: Dec. 13, 2023

(51) Int. Cl. H03K 17/76; H03K 17/10; H04B 1/00

(52) U.S. Cl. CPC H03K 17/76; H03K 17/10; H04B 1/005

(57) ABSTRACT

Broadband absorptive termination diode switches, and various embodiments and aspects thereof, are described. An example diode switch includes a common port, a first port, and a second port, a first switch arm between the first port and the common port, and a second switch arm between the second port and the common port. The first switch arm includes a first node and a second node each electrically coupled between and electrically separated from the first port and the common port. The first switch arm also includes a shunt diode electrically coupled between the first node and ground, a termination leg electrically coupled between the second node and ground, and a series diode electrically coupled between the first node and the second node. The use of the series diode between the first node and the second node results in broader bandwidth of operation in absorptive switches as compared to other designs.

### BACKGROUND

A PIN (P-type-Intrinsic-N-type) diode is a diode with an undoped intrinsic semiconductor region between a P-type semiconductor region and an N-type semiconductor region. The P-type and N-type regions are typically heavily doped because they are used for ohmic contacts. The inclusion of the intrinsic region between the P-type and N-type regions is in contrast to an ordinary PN diode, which does not include an intrinsic region. The P-type region is the anode of the PIN diode, and the N-type region is the cathode of the PIN diode.

If a positive voltage larger than a threshold value is applied to the anode of a PIN diode with respect to the cathode, a current will flow through the PIN diode and the impedance of the PIN diode will decrease. A PIN diode in a forward biased state can be represented as a resistor having a resistance that decreases to a minimum value as the current through the PIN diode increases. PIN diode switches are often used to control the path of radio frequency (RF) signals. Depending on the performance requirements, the switch can consist of all series diodes, all shunt diodes or a combination of series and shunt diodes.

### SUMMARY

Various examples and embodiments of broadband absorptive termination diode switches are described. An example diode switch includes a common port, a first port, and a second port, a first switch arm between the first port and the common port, and a second switch arm between the second port and the common port. The first switch arm includes a first node and a second node each electrically coupled between and electrically separated from the first port and the common port. The first switch arm also includes a shunt diode electrically coupled between the first node and ground, a termination leg electrically coupled between the second node and ground, and a series diode electrically coupled between the first node and the second node. The use of the series diode between the first node and the second node results in broader bandwidth of operation in absorptive switches as compared to other designs.

The diode switch can also include a second series diode electrically coupled between the common port and the first node. In another case, the diode switch can also include a transmission line electrically coupled between the common port and the first node. The diode switch can also include a first bias node electrically coupled to the first node, a bias diode electrically coupled between the first bias node and the first node, and a second bias diode electrically coupled between the second node and the termination leg, where the termination leg includes a second shunt diode and a resistor coupled in series between the second node and ground.

The second switch arm of the diode switch can include a third node and a fourth node each electrically coupled between and electrically separated from the second port and the common port, a second shunt diode electrically coupled between the third node and ground, a second termination leg electrically coupled between the fourth node and ground, and a second series diode electrically coupled between the third node and the fourth node. The diode switch can also include a third series diode electrically coupled between the common port and the third node. In another case, the diode switch can also include a transmission line electrically coupled between the common port and the third node.

In other aspects, a first intrinsic region thickness of at least one diode in the first switch arm can be different than a second intrinsic region thickness of at least one diode in the second switch arm. The diode switch can also include a third port. A third switch arm can be electrically coupled between the third port and the common port.

In another case, the second switch arm includes a third node and a fourth node each electrically coupled between and electrically separated from the second port and the common port, a second shunt diode electrically coupled between the third node and ground, a second termination leg electrically coupled between the fourth node and ground, and a transmission line electrically coupled between the third node and the fourth node.

Another example diode switch includes a common port, a first port, and a switch arm electrically coupled between the first port and the common port. The switch arm includes a first node and a second node each electrically coupled between and electrically separated from the first port and the common port, a shunt diode electrically coupled between the first node and ground, a termination leg electrically coupled between the second node and ground, and a series diode electrically coupled between the first node and the second node.

### BRIEF DESCRIPTION OF THE DRAWINGS

Aspects of the present disclosure can be better understood with reference to the following drawings. It is noted that the elements in the drawings are not necessarily to scale, with emphasis instead being placed upon clearly illustrating the principles of the embodiments. In the drawings, like reference numerals designate like or corresponding, but not necessarily the same, elements throughout the several views.

FIG. 1 illustrates an example diode switch according to various embodiments described herein.

FIG. 2 illustrates an example diode switch with broadband absorption termination according to various embodiments described herein.

FIG. 3 illustrates another example diode switch with broadband absorption termination according to various embodiments described herein.

FIG. 4 illustrates another example diode switch with broadband absorption termination and varied switch arm configurations according to various embodiments described herein.

FIG. 5 illustrates another example multi-arm diode switch with broadband absorption termination according to various embodiments described herein.

### DETAILED DESCRIPTION

PIN (P-type-Intrinsic-N-type) diodes are often used to control the path of radio frequency (RF) signals in switches. Depending on the type and performance requirements of an RF switch, the switch can consist of all series diodes, all shunt diodes, or a combination of series and shunt diodes.

A number of different types, topologies, and styles of PIN diode RF switches are known. Single pole (SP), double pole (DP), triple pole (3P), quadruple pole (4P), and other (e.g., greater) pole configurations are known in RF switches. Single throw (ST), double throw (DT), triple throw (3T), quadruple throw (4T), and other (e.g., greater) throw configurations are also known in RF switches.

PIN diode RF switches can be reflective or absorptive. In a reflective switch, the RF signal at each inactive or “off” input port is reflected back to the source. Reflective switches are relatively more simple in design and can handle higher power than most absorptive switches. Absorptive switches are designed to provide a matched termination at each inactive or “off” port and do not reflect (or reflect less) energy back to the source. Absorptive RF switches are designed for a certain level of power handling matched termination capability over a specified frequency bandwidth. The absorption performance of each RF switch can vary depending on a number of factors, including the frequency of the RF signals provided at the input terminals of the RF switch, the power level of the RF signals, and other factors. Many absorptive RF switches are designed for matched termination of RF signals having a particular frequency or band of frequencies.

In the context outlined above, broadband absorptive termination diode switches, and various embodiments and aspects thereof, are described herein. An example diode switch includes a common port, a first port, and a second port, a first switch arm between the first port and the common port, and a second switch arm between the second port and the common port. The first switch arm includes a first node and a second node each electrically coupled between and electrically separated from the first port and the common port. The first switch arm also includes a shunt diode electrically coupled between the first node and ground, a termination leg electrically coupled between the second node and ground, and a series diode electrically coupled between the first node and the second node. The use of the series diode between the first node and the second node results in broader bandwidth of operation in absorptive switches as compared to other designs.

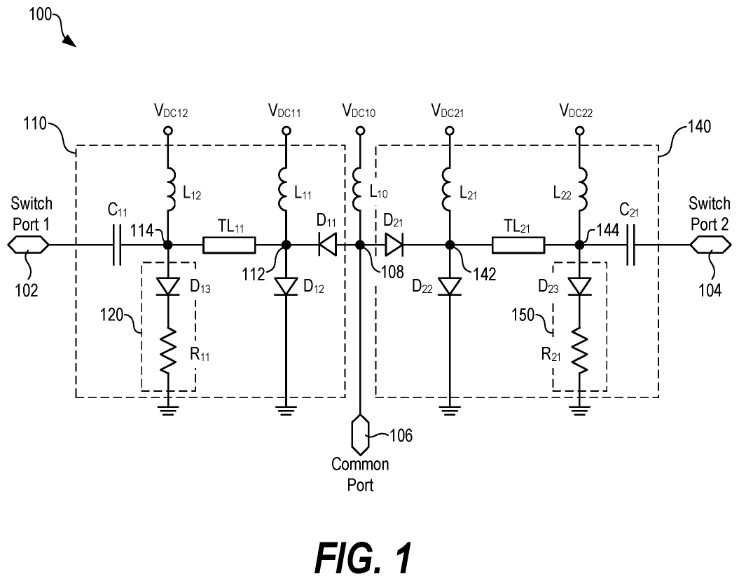

FIG. 1 illustrates an example diode switch 100 (also “switch 100”) according to various embodiments described herein. The switch 100 is illustrated as a representative example in FIG. 1. The switch 100 can be relied upon to control the path or paths of one or more RF signals. The switch 100 includes a number of input and output ports, PIN diodes, inductors, resistors, capacitors, transmission lines, and other components. The switch 100 is not exhaustively illustrated and, in some cases, can include additional components that are not illustrated in FIG. 1. In other cases, one or more of the components shown in FIG. 1 can be omitted. The switch 100 is also illustrated to include two switch arms, as described below, but the switch 100 can include any suitable number of switch arms, including one, two, three, four, five, six, or more switch arms. In other words, the switch 100 is an example SPDT switch, because it includes two switch arms, but the switch 100 could be implemented as a SPST switch, a SP3T switch, a SP4T switch, or a switch with any number of switch arms.

The switch 100 can be implemented in a number of different ways. As one example, the switch 100 can be implemented as an assembly of individual components, including a number of discrete PIN diodes, resistors, capacitors, inductors, and other components mounted on and electrically coupled with a printed circuit board (PCB). The switch 100 can also be implemented in other ways, however, including in a monolithic (i.e., integrated single chip) format.

The switch 100 includes a first switch port 102, a second switch port 104, a common port 106, a first switch arm 110, and a second switch arm 140. The first switch arm 110 is electrically coupled between a common node 108 in the switch 100 and the first switch port 102. The second switch arm 140 is electrically coupled between the common node 108 in the switch 100 and the second switch port 104. The switch 100 also includes a bias node V_{DC10} and an inductor L₁₀. The inductor L₁₀ is positioned between the bias node V_{DC10} and the common node 108. The common port 106 is directly coupled to the common node 108.

The first switch arm 110 includes diodes D₁₁, D₁₂, and D₁₃, a transmission line TL₁₁, a resistor R₁₁, inductors L₁₁ and L₁₂, a capacitor C₁₁, a first node 112, and a second node 114. The diode D₁₁ is electrically coupled between the common node 108 and the node 112 in the switch 100. More particularly, the anode of the diode D₁₁ is electrically coupled to the common node 108, and the cathode of the diode D₁₁ is electrically coupled to the node 112. The diode D₁₂ is electrically coupled between the node 112 and ground, with the anode of the diode D₁₂ electrically coupled to the node 112 and the cathode of the diode D₁₁ electrically coupled to ground. The transmission line TL₁₁ is electrically coupled between the node 112 and the node 114. The capacitor C₁₁ is electrically coupled between the second node 114 and the switch port 102.

The resistor R₁₁ and the diode D₁₃ form a termination leg 120 in the first switch arm 110. The termination leg 120 is electrically coupled between the node 114 and ground, with the diode D₁₃ being electrically coupled between the node 114 and the resistor R₁₁. The anode of the diode D₁₃ is electrically coupled to the node 114, and the cathode of the diode D₁₃ is electrically coupled to the resistor R₁₁. One end of the resistor R₁₁ is electrically coupled to the cathode of the diode D₁₃, and another end of the resistor R₁₁ is electrically coupled to ground.

The diode D₁₁ is a series diode in the switch arm 110 because it is electrically coupled in series between the common port 106 and the switch port 102. The diode D₁₂ is a shunt diode in the switch arm 110 because it is electrically coupled from the node 212, which is between the common port 106 and the switch port 102, to ground. The diode D₁₃ is also a type of shunt diode in the switch arm 110 because it is electrically coupled from the node 114 to ground.

The capacitor C₁₁ is electrically coupled in series between the node 114 and the first switch port 102. The capacitor C₁₁ provides direct current (DC) isolation between the first switch port 102 and the first switch arm 110. The inductor L₁₁ is electrically coupled between the bias node V_{DC11} and the node 112. The inductor L₁₂ is electrically coupled between the bias node V_{DC12} and the node 114. The inductors L₁₁ and L₁₂ operate as RF choke inductors between the nodes 112 and 114, respectively, and the bias nodes V_{DC11} and V_{DC12} for the application of bias voltages. The inductors L₁₁ and L₁₂ can also be referenced and embodied as DC feed inductors. A DC feed inductor is an example ideal RF choke inductor that behaves as a short for DC currents and as an open circuit for any alternating current (AC) signal. The inductors L₁₁ and L₁₂ are relied upon to stop RF signals from reaching the DC bias sources.

The second switch arm 140 includes diodes D₂₁, D₂₂, and D₂₃, a transmission line TL₂₁, a resistor R₂₁, inductors L₂₁ and L₂₂, a capacitor C₂₁, a first node 142, and a second node 144. The diode D₂₁ is electrically coupled between the common node 108 in the switch 100 and the node 142. More particularly, the anode of the diode D₂₁ is electrically coupled to the common node 108, and the cathode of the diode D₂₁ is electrically coupled to the node 142. The diode D₂₂ is electrically coupled between the node 142 and ground, with the anode of the diode D₂₂ electrically coupled to the node 142 and the cathode of the diode D₂₂ electrically coupled to ground. The transmission line TL₂₁ is electrically coupled between the node 142 and the node 144. The capacitor C₂₁ is electrically coupled between the node 144 and the second switch port 104.

The resistor R₂₁ and the diode D₂₃ form a termination leg 150 in the second switch arm 140. The termination leg 150 is electrically coupled between the node 144 and ground, with the diode D₂₃ being electrically coupled between the node 144 and the resistor R₂₁. The anode of the diode D₂₃ is electrically coupled to the node 144, and the cathode of the diode D₂₃ is electrically coupled to the resistor R₂₁. One end of the resistor R₂₁ is electrically coupled to the cathode of the diode D₂₃, and another end of the resistor R₂₁ is electrically coupled to ground.

The diode D₂₁ is a series diode in the switch arm 110 because it is electrically coupled in series between the common node 108 and the switch port 104. The diode D₂₂ is a shunt diode in the switch arm 140 because it is electrically coupled between the node 142 and ground. The diode D₂₃ is also a type of shunt diode in the switch arm 140 because it is electrically coupled to ground.

The capacitor C₂₁ is electrically coupled in series between the node 144 and the second switch port 104. The capacitor C₂₁ provides DC isolation between the second switch port 104 and the second switch arm 140. The inductor L₂₁ is electrically coupled between the bias node V_{DC21} and the node 142. The inductor L₂₂ is electrically coupled between the bias node V_{DC22} and the node 144. The inductors L₂₁ and L₂₂ operate as RF choke inductors between the nodes 142 and 144, respectively, and the bias nodes V_{DC21} and V_{DC22} for the application of bias voltages. The inductors L₂₁ and L₂₂ can also be referenced and embodied as DC feed inductors. The inductors L₂₁ and L₂₂ are relied upon to stop RF signals from reaching the DC bias sources.

The diodes D₁₁, D₁₂, and D₁₃ in the switch arm 110 are PIN diodes, and the diodes D₂₁, D₂₂, and D₂₃ in the switch arm 140 are also PIN diodes. As noted above, the switch 100 is a type of SPDT PIN diode switch as shown in FIG. 1. The switch 100 is an SPDT switch because it includes two switch arms, but the switch 100 could be implemented as a SP3T switch, a SP4T switch, or a switch with any number of switch arms.

In operation, the switch 100 can be relied upon to control the path of a first RF signal between the first switch port 102 and the common port 106. The switch 100 can also be relied upon to control the path of a second RF signal between the second switch port 104 and the common port 106. More particularly, the switch 100 can control the path of RF signals between the switch port 102 and the common port 106 based on the application of bias voltages to the bias nodes V_{DC10}, V_{DC11}, and V_{DC12}. As one example, the diodes D₁₁, D₁₂, and D₁₃ in the switch arm 110 can be biased to either “pass” an RF signal from the switch port 102 to the common port 106 or to “stop” the RF signal at the switch port 102 from reaching the common port 106. The switch 100 can also control the path of RF signals between the switch port 104 and the common port 106 based on the application of bias voltages to the bias nodes V_{DC10}, V_{DC21}, and V_{DC22}. As one example, the diodes D₂₁, D₂₂, and D₂₃ in the switch arm 140 can be biased to either “pass” an RF signal from the switch port 104 to the common port 106 or to “stop” the RF signal at the switch port 104 from reaching the common port 106.

The switch 100 is an absorptive switch and the termination legs 120 and 150 are designed to provide, at least in part, a matched termination (e.g., a 50 (termination) for RF signals present on the switch ports 102 and 104, respectively, if those signals are not passed. Thus, when an RF input signal is applied to the switch port 102 and stopped (e.g., not passed to the common port 106), the switch 100 is designed to absorb the RF signal applied to the switch port 102 and not reflect the RF signal back to the source. The termination leg 120 and the transmission line TL₁₁ in the switch arm 110 are designed to absorb the RF signal when the switch arm 110 is biased to stop the RF signal.

To stop and absorb the RF signal applied to the switch port 102, the diode D₁₂ can be forward biased by a bias voltage applied at the bias node V_{DC11}, and the node 112 will appear as a short to ground through the diode D₁₂ in that case. The energy of the RF signal applied to the switch port 102 will be reflected and not absorbed at a short. Thus, the transmission line TL₁₁ in the switch arm 110 is relied upon to convert the short at the node 112 to an open stub. The termination leg 120 provides a resistive load to absorb the energy of the RF signal at the open stub. To that end, the diode D₁₃ can be forward biased by a bias voltage applied at the bias node V_{DC12}, and the resistive load of the resistor R₁₁ will appear at the node 114 to absorb the RF signal at the open stub at one end of the transmission line TL₁₁ in the switch arm 110.

The length of the transmission line TL₁₁ can be designed and tailored to operate as an open stub based on the frequency characteristics of the RF signal at the switch port 102, as would be understood in the field. The length of the transmission line TL₁₁ can be designed and implemented as a quarter-wavelength (i.e., λ/4) transmission line based on one quarter of the wavelength of the RF signal presented at the switch port 102, for matched performance of the transmission line TL₁₁ as an open stub. A quarter-wavelength transformer, such as the transmission line TL₁₁, has frequency band limitations, however, and operates most effectively as an open stub in a relatively narrow center frequency band. Thus, the absorption performance of the switch arm 110 depends in part on the design of the transmission line TL₁₁ and the match (or possible mismatch) between the frequency of the RF signal at switch port 102 and the length of the transmission line TL₁₁.

The limitations of the transmission line TL₁₁ to operate as an ideal open stub in the switch arm 110, depending on the frequency of the RF signal at switch port 102, is a limitation of the absorption performance of the switch 100. The switch arm 110 can be considered to have a relatively narrow band for best absorption performance as compared to other solutions described herein. Similarly, the limitations of the transmission line TL₂₁ to operate as an ideal open stub in the switch arm 140 is another limitation of the absorption performance of the switch 100. The use of the transmission lines TL₁₁ and TL₂₁ results in a bandwidth limitation for the switch 100 and particularly for the absorptive performance of the switch 100 over a range of RF signal frequencies through the switch ports 102 and 104. For example, the performance of the switch 100 can adhere to one or more specification for absorption or other criteria within a frequency range from 10 to 20 Ghz, but the switch 100 may fail to perform up to the specifications for absorption or other criteria within a wider frequency range from 10 to 50 Ghz.

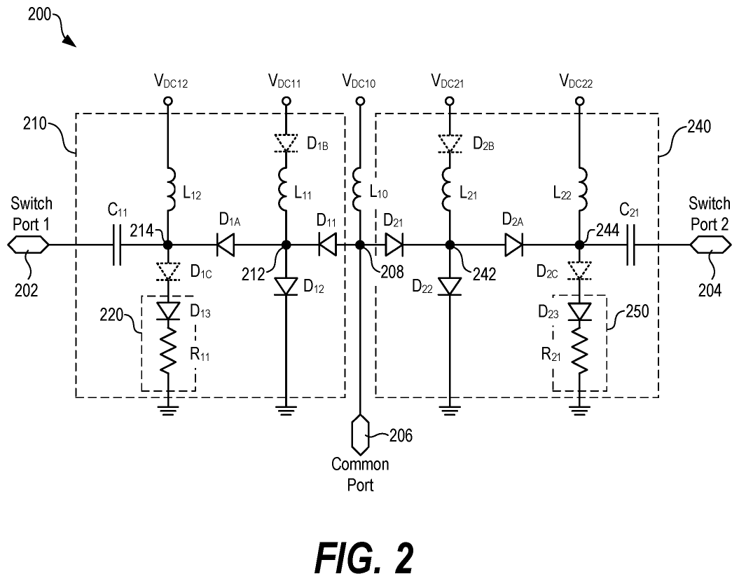

FIG. 2 illustrates an example diode switch 200 with broadband absorption termination according to various embodiments described herein. The switch 200 is illustrated as a representative example in FIG. 2. The switch 200 can be relied upon to control the path or paths of one or more RF signals. The switch 200 includes a number of input and output ports, PIN diodes, inductors, resistors, capacitors, transmission lines, and other components. The switch 200 is designed for broadband absorptive termination, as described herein, although the concepts of broadband absorptive termination can also be applied to other types, styles, and topologies of switches. The switch 200 is not exhaustively illustrated and, in some cases, can include additional components that are not illustrated in FIG. 2. In other cases, one or more of the components shown in FIG. 2 can be omitted. The switch 200 is also illustrated to include two switch arms, as described below, but the switch 200 can include any suitable number of switch arms, including one, two, three, four, five, six, or more switch arms. In other words, the switch 200 is an example SPDT switch, because it includes two switch arms, but the switch 200 could be implemented as a SPST switch, a SP3T switch, a SP4T switch, or a switch with any number of switch arms.

The switch 200 can be implemented in a number of different ways. As one example, the switch 200 can be implemented as an assembly of individual components, including a number of discrete PIN diodes, resistors, capacitors, inductors, and other components mounted on and electrically coupled with a PCB. The switch 200 can also be implemented in other ways, however, including in a monolithic format.

The switch 200 includes a first switch port 202, a second switch port 204, a common port 206, a first switch arm 210, and a second switch arm 240. The first switch arm 210 is electrically coupled between a common node 208 in the switch 200 and the first switch port 202. The second switch arm 240 is electrically coupled between the common node 208 in the switch 200 and the second switch port 204. The switch 200 also includes a bias node V_{DC10} and an inductor L₁₀. The inductor L₁₀ is positioned between the bias node V_{DC10} and the common node 208. The common port 206 is directly coupled to the common node 208 in the example shown.

The first switch arm 210 includes diodes D₁₁, D₁₂, and D₁₃, a resistor R₁₁, inductors L₁₁ and L₁₂, a capacitor C₁₁, a first node 212, and a second node 214. The node 212 is electrically separated from the common node 208 by the diode D₁₁. The first switch arm 210 also includes diode DIA. The node 212 is electrically separated from the node 214 by the diode DIA. The node 214 is electrically separated from the switch port 202 by the capacitor C₁₁. The first switch arm 210 also includes diodes D_{1B} and D_{1C} in some embodiments. The diodes DIB and D_{1C} can be included and relied upon for biasing the diode D_{1A} in some cases. However, one or both of the diodes D_{1B} and D_{1C} can also be omitted from the switch arm 210 in other examples, as a range of different biasing approaches can be relied upon for biasing the diode DIA.

The diode D₁₁ is electrically coupled between the common node 208 and the node 212 in the switch arm 210. More particularly, the anode of the diode D₁₁ is electrically coupled to the common node 208, and the cathode of the diode D₁₁ is electrically coupled to the node 212. In some cases, as shown in FIG. 2, the diode D₁₁ directly couples the common node 208 and the node 212 without any other intervening components between the common node 208 and the node 212.

The diode D₁₂ is electrically coupled between the node 212 and ground, with the anode of the diode D₁₂ electrically coupled to the node 212 and the cathode of the diode D₁₂ electrically coupled to ground. In some cases, as shown in FIG. 2, the diode D₁₂ directly couples the node 212 to ground without any other intervening components between the node 212 and ground.

The diode D_{1A} is electrically coupled between the node 212 and the node 214 in the switch arm 210. More particularly, the anode of the diode D_{1A} is electrically coupled to the node 212, and the cathode of the diode D_{1A} is electrically coupled to the node 214. In some cases, as shown in FIG. 2, the diode D_{1A} directly couples the node 212 and the node 214 without any other intervening components between the node 212 and the node 214.

The resistor R₁₁ and the diode D₁₃ form a termination leg 220 in the first switch arm 210. If the diode D_{1C} is omitted from the first switch arm 210, then the termination leg 220 is electrically coupled between the node 214 and ground. In that case, the anode of the diode D₁₃ is electrically coupled to the node 214, and the cathode of the diode D₁₃ is electrically coupled to the resistor R₁₁. One end of the resistor R₁₁ is electrically coupled to the cathode of the diode D₁₃, and another end of the resistor R₁₁ is electrically coupled to ground. Alternatively, if the diode D_{1C} is included in first switch arm 210, then the anode of the diode D_{1C} is electrically coupled to the node 214 and the cathode of the diode D_{1C} is electrically coupled to the cathode of the diode D₁₃ in the termination leg 220.

The diode D₁₁ is a series diode in the switch arm 210 because it is electrically coupled in series between the common port 206 and the switch port 202. The diode D₁₂ is a shunt diode in the switch arm 210 because it is electrically coupled from the node 212, which is between the common port 206 and the switch port 202, to ground. The diode D₁₃ is also a type of shunt diode in the switch arm 210 because it is electrically coupled from the node 214 to ground.

The capacitor C₁₁ is electrically coupled in series between the node 214 and the first switch port 202. The capacitor C₁₁ provides DC isolation between the first switch port 202 and the first switch arm 210. The inductor L₁₁ is electrically coupled between the bias node V_{DC11} and the node 212. The inductor L₁₂ is electrically coupled between the bias node V_{DC12} and the node 214. The inductors L₁₁ and L₁₂ operate as RF choke inductors between the nodes 212 and 214, respectively, and the bias nodes V_{DC11} and V_{DC12} for the application of bias voltages. The inductors L₁₁ and L₁₂ can also be referenced and embodied as DC feed inductors. The diode D_{1B} is, when included in the switch arm 210, electrically coupled in series with the inductor L₁₁.

The second switch arm 240 includes diodes D₂₁, D₂₂, and D₂₃, a resistor R₂₁, inductors L₂₁ and L₂₂, a capacitor C₂₁, a first node 242, and a second node 244. The node 242 is electrically separated from the common node 208 by the diode D₂₁. The second switch arm 240 also includes diode D_{2A}. The node 242 is electrically separated from the node 244 by the diode D_{2A}. The node 244 is electrically separated from the switch port 204 by the capacitor C₂₁. The second switch arm 240 also includes diodes D_{2B} and D_{2C} in some embodiments. The diodes D_{2B} and D_{2C} can be included and relied upon for biasing the diode D_{2A} in some cases. However, one or both of the diodes D_{2B} and D_{2C} can also be omitted from the switch arm 240 in other examples, as a range of different biasing approaches can be relied upon for biasing the diode D_{2A}.

The diode D₂₁ is electrically coupled between the common node 208 and the node 214 in the switch arm 240. More particularly, the anode of the diode D₂₁ is electrically coupled to the common node 208, and the cathode of the diode D₂₁ is electrically coupled to the node 242. In some cases, as shown in FIG. 2, the diode D₂₁ directly couples the common node 208 and the node 242 without any other intervening components between the common node 208 and the node 242.

The diode D₂₂ is electrically coupled between the node 242 and ground, with the anode of the diode D₂₂ electrically coupled to the node 242 and the cathode of the diode D₂₂ electrically coupled to ground. In some cases, as shown in FIG. 2, the diode D₂₂ directly couples the node 242 to ground without any other intervening components between the node 212 and ground.

The resistor R₂₁ and the diode D₂₃ form a termination leg 250 in the second switch arm 240. If the diode D_{2C} is omitted from the switch arm 240, then the termination leg 250 is electrically coupled between the node 244 and ground. In that case, the anode of the diode D₂₃ is electrically coupled to the node 244, and the cathode of the diode D₂₃ is electrically coupled to the resistor R₂₁. One end of the resistor R₂₁ is electrically coupled to the cathode of the diode D₂₃, and another end of the resistor R₂₁ is electrically coupled to ground. Alternatively, if the diode D_{2C} is included in second switch arm 240, then the anode of the diode D_{2C} is electrically coupled to the node 244 and the cathode of the diode D_{2C} is electrically coupled to the cathode of the diode D₂₃ in the termination leg 250.

The diode D₂₁ is a series diode in the switch arm 210 because it is electrically coupled in series between the common node 208 and the switch port 204. The diode D₂₂ is a shunt diode in the switch arm 240 because it is electrically coupled between the node 242 and ground. The diode D₂₃ is also a type of shunt diode in the switch arm 240 because it is electrically coupled to ground.

The capacitor C₂₁ is electrically coupled in series between the node 244 and the second switch port 204. The capacitor C₂₁ provides DC isolation between the second switch port 204 and the second switch arm 240. The inductor L₂₁ is electrically coupled between the bias node V_{DC21} and the node 242. The inductor L₂₂ is electrically coupled between the bias node V_{DC22} and the node 244. The inductors L₂₁ and L₂₂ operate as RF choke inductors between the nodes 242 and 244, respectively, and the bias nodes V_{DC21} and V_{DC22} for the application of bias voltages. The inductors L₂₁ and L₂₂ can also be referenced and embodied as DC feed inductors. The diode D_{2B} is, when included in the switch arm 240, electrically coupled in series with the inductor L₂₁.

In one embodiment, the diodes D₁₁, D₁₂, D₁₃, D_{1A}, D_{1B}, and D_{1C} in the switch arm 210 are PIN diodes, and the diodes D₂₁, D₂₂, D₂₃, D_{2A}, D_{2B}, and D_{2C} in the switch arm 240 are also PIN diodes. In one case, the diodes D₁₁, D₁₂, D₁₃, D_{1A}, D_{1B}, and D_{1C} in the switch arm 210 can be the same as each other. That is, each of the diodes D₁₁, D₁₂, D₁₃, D_{1A}, D_{1B}, and D_{1C} can be the same type of PIN diode, each having the same intrinsic layer thickness and the same dopant types and densities in the P-type and N-type regions. In other cases, one or more of the diodes D₁₁, D₁₂, D₁₃, D_{1A}, D_{1B}, and D_{1C} in the switch arm 210 can be different than one or more other diodes in the switch arm 210. As just one example, the thickness of the intrinsic layer of the diode D_{1A} can be different than the thickness of the intrinsic layer of the diode D₁₁, and other variations are within the scope of the embodiments.

Similarly, in one case, the diodes D₂₁, D₂₂, D₂₃, D_{2A}, D_{2B}, and D_{2C} in the switch arm 240 can be the same as each other. That is, each of the diodes D₂₁, D₂₂, D₂₃, D_{2A}, D_{2B}, and D_{2C} can be the same type of PIN diode, each having the same intrinsic layer thickness and the same dopant types and densities in the P-type and N-type regions. In other cases, one or more of the diodes D₂₁, D₂₂, D₂₃, D_{2A}, D_{2B}, and D_{2C} in the switch arm 240 can be different than one or more other diodes in the switch arm 240. As just one example, the thickness of the intrinsic layer of the diode D_{2A} can be different than the thickness of the intrinsic layer of the diode D₂₁, and other variations are within the scope of the embodiments.

In operation, the switch 200 can be relied upon to control the path of a first RF signal between the first switch port 202 and the common port 206. The switch 200 can also be relied upon to control the path of a second RF signal between the second switch port 204 and the common port 206. More particularly, the switch 200 can control the path of RF signals between the switch port 202 and the common port 206 based on the application of bias voltages to the bias nodes V_{DC10}, V_{DC11}, and V_{DC12}. As one example, the diodes D₁₁, D₁₂, D₁₃, and DA in the switch arm 210 can be biased to either “pass” an RF signal from the switch port 202 to the common port 206 or to “stop” the RF signal at the switch port 202 from reaching the common port 206. The switch 200 can also control the path of RF signals between the switch port 204 and the common port 206 based on the application of bias voltages to the bias nodes V_{DC20}, V_{DC21}, and V_{DC22}. As one example, the diodes D₂₁, D₂₂, D₂₃, and D_{2A} in the switch arm 240 can be biased to either “pass” an RF signal from the switch port 204 to the common port 206 or to “stop” the RF signal at the switch port 204 from reaching the common port 206.

Like the switch 100 shown in FIG. 1, the switch 200 is an absorptive switch and the termination legs 220 and 250 are designed to provide, at least in part, a matched termination for RF signals present on the switch ports 202 and 204, respectively, if those signals are not passed. Thus, when an RF input signal is applied to the switch port 202 and stopped (e.g., not passed to the common port 206), the switch 200 is designed to absorb the RF signal applied to the switch port 202 and not reflect the RF signal back to the source. The termination leg 220 and the diode D_{1A} in the switch arm 210 are designed to absorb the RF signal when the switch arm 210 is biased to stop the RF signal.

To stop and absorb an RF signal applied to the switch port 202, the diode D₁₂ can be forward biased by a bias voltage applied at the bias node V_{DC11}, and the node 212 will appear as a short to ground through the diode D₁₂ in that case. The energy of the RF signal applied to the switch port 202 would typically be reflected back from the short presented at the node 212. However, the diode D_{1A} in the switch arm 210 can be relied upon to present a high impedance or a capacitance before the node 212. The diode D_{1A} can be forward biased with a small forward bias current to present a high impedance or be reverse biased to present a capacitance. The diode D_{1A} can present a high impedance of hundreds of kiloohms or greater when forward biased with a small current. The diode D_{1A} can also present a capacitance when reverse biased.

To present a high impedance, the diode D_{1A} can be forward biased with a small forward bias current through the application of bias voltages at the bias nodes V_{DC11} and V_{DC12}. The diodes D_{1B} and D_{1C} can facilitate the application of a forward bias across the diode D_{1A} in some cases depending on the potentials applied at the bias nodes V_{DC11} and V_{DC12}. A range of different bias voltages can be respectively applied at the bias nodes V_{DC11} and V_{DC12}, however, and the diodes D_{1B} and D_{1C} can be omitted in some cases.

The diodes D₁₃ and D_{1C} can also be forward biased by a bias voltage applied at the bias node V_{DC12}, and the resistive load of the resistor R₁₁ will appear at the node 214 to absorb the RF signal at node 214. The termination leg 220 thus provides a resistive load to absorb the energy of the RF signal applied to the switch port 202.

Overall, the diode D_{1A} can be biased to present a high impedance at the node 214 and is a type of substitute or replacement for the transmission line TL₁₁ in the switch 100. The operating performance of the diode D_{1A} as a high impedance varies less over changes in the frequency of the RF signal at the switch port 202 than the operating performance of the transmission line TL₁₁ varies as an open stub. Thus, the absorption performance of the switch arm 210 in the switch 200 is improved over a wider bandwidth of RF signals as compared to the switch arm 110 in the switch 100. The switch arm 210 can be considered to have a relatively wider band for absorption performance as compared to the switch arm 110. The use of the diode D_{1A} results in broader bandwidth of operation for the switch 200 and particularly for the absorptive performance of the switch 200 over a wider range of RF signal frequencies through the switch port 202.

To stop and absorb an RF signal applied to the switch port 204, the diode D₂₂ can be forward biased by a bias voltage applied at the bias node V_{DC21}, and the node 242 will appear as a short to ground through the diode D₂₂ in that case. The energy of the RF signal applied to the switch port 204 would typically be reflected back from the short presented at the node 242. However, the diode D_{2A} in the switch arm 240 can be relied upon to present a high impedance or a capacitance before the node 242. The diode D_{2A} can be forward biased with a small forward bias current to present a high impedance or be reverse biased to present a capacitance. The diode D_{2A} can present a high impedance of hundreds of kiloohms or greater when forward biased with a small current. The diode D_{2A} can also present a capacitance when reverse biased.

To present a high impedance, the diode D_{2A} can be forward biased with a small forward bias current through the application of bias voltages at the bias nodes V_{DC21} and V_{DC22}. The diodes D_{2B} and D_{2C} can facilitate the application of a forward bias across the diode D_{2A} in some cases depending on the potentials applied at the bias nodes V_{DC21} and V_{DC22}. A range of different bias voltages can be respectively applied at the bias nodes V_{DC21} and V_{DC22}, however, and the diodes D_{2B} and D_{2C} can be omitted in some cases.

The diodes D₂₃ and D_{2C} can also be forward biased by a bias voltage applied at the bias node V_{DC22}, and the resistive load of the resistor R₂₁ will appear at the node 244 to absorb the RF signal at node 244. The termination leg 250 thus provides a resistive load to absorb the energy of the RF signal applied to the switch port 204.

Overall, the diode D_{2A} can be biased to present a high impedance at the node 244 and is a type of substitute or replacement for the transmission line TL₂₁ in the switch 100. The operating performance of the diode D_{2A} as a high impedance varies less over changes in the frequency of the RF signal at the switch port 204 than the operating performance of the transmission line TL₂₁ varies as an open stub. Thus, the absorption performance of the switch arm 240 in the switch 200 is improved over a wider bandwidth of RF signals as compared to the switch arm 140 in the switch 100. The switch arm 240 can be considered to have a relatively wider band for absorption performance as compared to the switch arm 140. The use of the diode D_{2A} results in broader bandwidth of operation for the switch 200 and particularly for the absorptive performance of the switch 200 over a wider range of RF signal frequencies through the switch port 204.

The performance of the switch 200 shown in FIG. 2 can adhere to one or more specification for absorption or other criteria within a wider frequency range than the switch 100 shown in FIG. 1. For example, the performance of the switch 100 can adhere to one or more specification for absorption or other criteria within a frequency range from 10 to 20 Ghz, but the switch 100 may fail to perform up to the specifications for absorption or other criteria within a wider frequency range from 10 to 50 Ghz. On the other hand, the performance of the switch 200 can adhere to one or more specification for absorption or other criteria within a frequency range from 10 to 40 Ghz. The frequency ranges are referenced as examples, however, and the concepts described herein are not limited to use with RF signals of any particular frequency or bandwidth.

The performance of the switch 200 can adhere to specifications for absorption within a wider bandwidth or range of frequencies than the switch 100. The replacement or substitution of the transmission lines TL₁₁ and TL₂₁ in the switch 100 with the diodes D_{1A} and D_{2A} in the switch 200 offers broader-band absorptive termination in the switch 200. The substitution carries a compromise, however, in that the forward-biased voltage drop across the diodes D_{1A} and D_{2A} can result in power loss for the RF signals passing through the diodes D_{1A} and D_{2A}.

Among other applications, the switch 200 can be relied upon as a transmit/receive (T/R) switch with one of the switch arms 210 and 240 used for transmission and another one used for reception. Some monolithic multi-throw switches incorporate PIN diodes having the same “I” region thickness for all PIN diodes, regardless of the intended functional capability of each switch arm. That monolithic approach results in a compromise solution relative to insertion loss, isolation, power handling, linearity, and distortion because it does not account for the specific functional responses of different switch arms. Primary design concerns for a transmit arm in a T/R switch can include incident power handling, isolation, linearity, and distortion, while primary design concerns for a receive arm can include insertion loss and sensitivity. Thus, the use of PIN diodes having different intrinsic “I” region thicknesses in the switch arms 210 and 240 may be preferable and for some applications.

For tailored functional responses in the switch arms 210 and 240, all of the diodes D₁₁, D₁₂, D₁₃, D_{1A}, D_{1B}, and D_{1C} in the switch arm 210 can be the same as each other or one or more of the diodes D₁₁, D₁₂, D₁₃, D_{1A}, D_{1B}, and D_{1C} can be different than another one or more of the diodes. Similarly, all of the diodes D₂₁, D₂₂, D₂₃, D_{2A}, D_{2B}, and D_{2C} in the switch arm 240 can be the same as each other or one or more of the diodes D₂₁, D₂₂, D₂₃, D_{2A}, D_{2B}, and D_{2C} can be different than another one or more of the diodes. In other examples, all of the diodes in the switch arm 210 can be the same as each other and all of the diodes in the switch arm 240 can be the same as each other, but one or more of the diodes in the switch arm 210 can be different than one or more of the diodes in the switch arm 240. Among the diodes in the switch arms 210 and 240, the diodes can have different dopant types, different dopant densities, different intrinsic “I” layer thicknesses, and other differences.

To achieve tailored functional responses in the switch arms 210 and 240 in a monolithic format, the diodes in the switch arms 210 and 240 can be manufactured according to the approach described in U.S. Pat. No. 11,574,906, titled “Monolithic Multi-I Region Diode Switches,” filed Feb. 28, 2020. As a more particular example, the diode D₁₁ in the switch arm 210 and the diode D₂₁ in the switch arm 240 can be embodied using a combination of the PIN diodes of the structures shown in FIG. 1A, 4A, 4B, or 5 in U.S. Pat. No. 11,574,906 with PIN diodes of different “I” region thicknesses. As another example, the diode D₁₂ in the switch arm 210 and the diode D₂₂ in the switch arm 240 can be embodied using a combination of the PIN diodes of the structures shown in FIG. 1A, 4A, 4B, or 5 in U.S. Pat. No. 11,574,906 with PIN diodes of different “I” region thicknesses. As still another example, the diode D_{1A} in the switch arm 210 and the diode D_{2A} in the switch arm 240 can be embodied using a combination of the PIN diodes of the structures shown in FIG. 1A, 4A, 4B, or 5 in U.S. Pat. No. 11,574,906 with PIN diodes of different “I” region thicknesses.

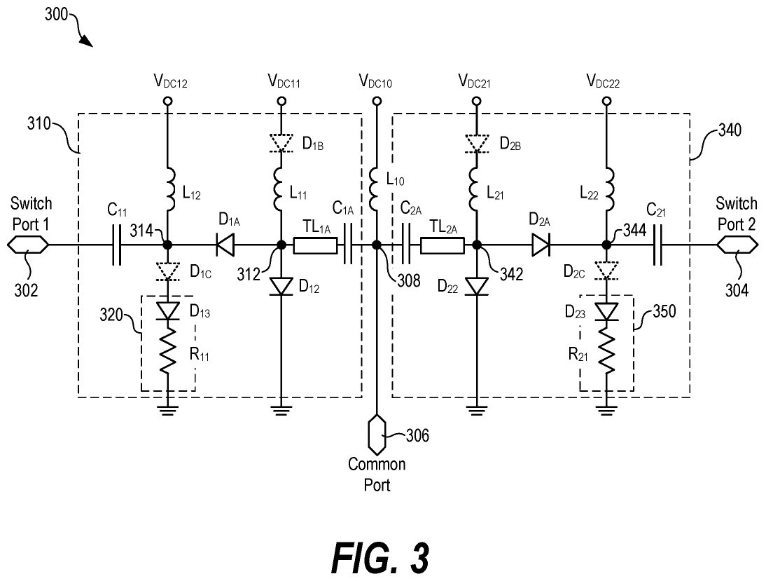

FIG. 3 illustrates another example diode switch 300 with broadband absorption termination according to various embodiments described herein. The switch 300 is illustrated as a representative example in FIG. 3. The switch 300 can be relied upon to control the path or paths of one or more RF signals. The switch 300 includes a number of input and output ports, PIN diodes, inductors, resistors, capacitors, transmission lines, and other components. The switch 300 is designed for broadband absorptive termination, as described herein, although the concepts of broadband absorptive termination can also be applied to other types, styles, and topologies of switches. The switch 300 is not exhaustively illustrated and, in some cases, can include additional components that are not illustrated in FIG. 3. In other cases, one or more of the components shown in FIG. 3 can be omitted. The switch 300 is also illustrated to include two switch arms, as described below, but the switch 300 can include any suitable number of switch arms, including one, two, three, four, five, six, or more switch arms. In other words, the switch 300 is an example SPDT switch, because it includes two switch arms, but the switch 300 could be implemented as a SPST switch, a SP3T switch, a SP4T switch, or a switch with any number of switch arms. The switch 300 can be implemented as an assembly of individual components, in a monolithic format, and in other ways.

The switch 300 includes a first switch port 302, a second switch port 304, a common port 306, a first switch arm 310, and a second switch arm 340. The first switch arm 310 is electrically coupled between a common node 308 in the switch 300 and the first switch port 302. The second switch arm 340 is electrically coupled between the common node 308 in the switch 300 and the second switch port 304. In the first switch arm 310, a first node 312 and a second node 314 is each electrically coupled between and electrically separated from the first switch port 302 and the common port 306. In the second switch arm 340, a first node 342 and a second node 344 is each electrically coupled between and electrically separated from the second switch port 304 and the common port 306.

The first switch arm 310 in the switch 300 is similar to the first switch arm 210 in the switch 200 shown in FIG. 2. However, the switch arm 310 does not include the diode D₁₁. Instead, the switch arm 310 includes a transmission line T_{1A} and a capacitor CIA electrically connected between the common node 308 and the node 312. Similarly, the second switch arm 340 in the switch 300 is similar to the second switch arm 240 in the switch 200 shown in FIG. 2. However, the switch arm 340 does not include the diode D₂₁. Instead, the switch arm 340 includes a transmission line T_{2A} and a capacitor C_{2A} electrically connected between the common node 308 and the node 342.

Like the switches 100 and 200 shown in FIGS. 1 and 2, the switch 300 is an absorptive switch and the termination legs 320 and 350 are designed to provide, at least in part, a matched termination for RF signals present on the switch ports 302 and 304, respectively, if those signals are not passed. Thus, when an RF input signal is applied to the switch port 302 and stopped (e.g., not passed to the common port 306), the switch 300 is designed to absorb the RF signal applied to the switch port 302 and not reflect the RF signal back to the source. The termination leg 320 and the diode D_{1A} in the switch arm 310 are designed to absorb the RF signal when the switch arm 310 is biased to stop the RF signal, as described herein. Similarly, when an RF input signal is applied to the switch port 304 and stopped (e.g., not passed to the common port 306), the switch 300 is designed to absorb the RF signal applied to the switch port 304 and not reflect the RF signal back to the source. The termination leg 350 and the diode D_{2A} in the switch arm 340 are designed to absorb the RF signal when the switch arm 340 is biased to stop the RF signal, as described herein.

The performance of the switch 300 shown in FIG. 3 can adhere to one or more specification for absorption or other criteria within a wider frequency range than the switch 100 shown in FIG. 1. For example, the performance of the switch 300 can adhere to one or more specification for absorption or other criteria within a frequency range from 10 to 20 Ghz, but the switch 100 may fail to perform up to the specifications for absorption or other criteria within a wider frequency range from 10 to 50 Ghz. On the other hand, the performance of the switch 300 can adhere to one or more specification for absorption or other criteria within a frequency range from 10 to 40 Ghz. The frequency ranges are referenced as examples, however, and the concepts described herein are not limited to use with RF signals of any particular frequency or bandwidth.

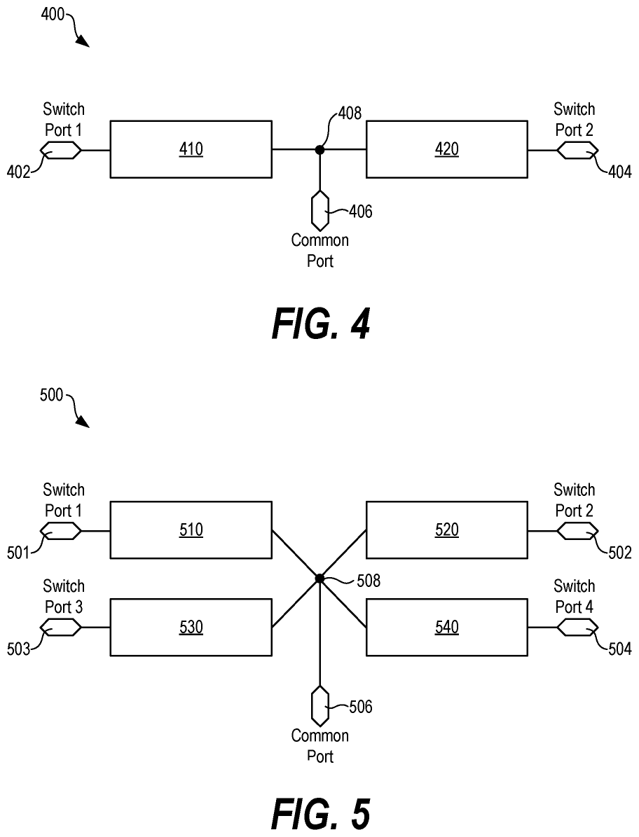

FIG. 4 illustrates another example diode switch 400 with broadband absorption termination and varied switch arm configurations. The switch 400 includes a first switch port 402, a second switch port 404, a common port 406, a first switch arm 410, and a second switch arm 420. The first switch arm 410 is electrically coupled between a common node 408 in the switch 400 and the first switch port 402. The second switch arm 420 is electrically coupled between the common node 408 in the switch 400 and the second switch port 404.

The switch 400 can be designed as a T/R switch in one embodiment. The first switch arm 410 can be designed as a transmit arm, and the second switch arm 420 can be designed as a receive arm. For tailored T/R functional responses in the switch arms 410 and 420, the switch arms 410 and 420 can have diodes with different dopant types, different dopant densities, different intrinsic “I” layer thicknesses, and other differences described herein. The switch arms 410 and 420 can also have different configurations in some cases. For example, the first switch arm 410 can be embodied as one of the switch arms in the switch 100 shown in FIG. 1, as one of the switch arms in the switch 200 shown in FIG. 2, or as one of the switch arms in the switch 300 shown in FIG. 3. The second switch arm 420 can be configured as another one of the switch arms among the switches 100, 200, and 300 shown in FIGS. 1-3. As such, the switch 400 can be designed to have varied switch arm configurations.

FIG. 5 illustrates another example multi-arm diode switch 500 with broadband absorption termination. The switch 500 includes a first switch port 501, a second switch port 502, a third switch port 503, a fourth switch port 504, a common port 506, a first switch arm 510, a second switch arm 520, a third switch arm 530, and a fourth switch arm 540. The switch 500 is an example of a single pole, quadruple throw (SP4T) switch. For tailored functional responses in the switch arms 510, 520, 530, and 540, the switch arms 510, 520, 530, and 540 can have diodes with different dopant types, different dopant densities, different intrinsic “I” layer thicknesses, and other differences described herein. The switch arms 510, 520, 530, and 540 can also have different configurations in some cases. For example, each of the switch arms 510, 520, 530, and 540 can be embodied as one of the switch arms shown FIGS. 1-3 and described herein. As such, the switch 500 can be designed to have varied switch arm configurations.

The features, structures, or characteristics described above may be combined in one or more embodiments in any suitable manner, and the features discussed in the various embodiments are interchangeable in many cases. In the foregoing description, numerous specific details are provided in order to fully understand the embodiments of the present disclosure. However, a person skilled in the art will appreciate that the technical solution of the present disclosure may be practiced without one or more of the specific details, or other methods, components, materials, and the like may be employed. In other instances, well-known structures, materials, or operations are not shown or described in detail to avoid obscuring aspects of the present disclosure.

Although relative terms such as “over,” “under,” “upper,” “lower,” “top,” “bottom,” “right,” and “left” may be used to describe the relative spatial relationships of certain structural features, these terms are used for convenience only, as a direction in the examples. When a structure or feature is described as being “over” (or formed over) another structure or feature, the structure can be positioned over the other structure, with or without other structures or features intervening between them. When two components are described as being “connected to” or “coupled to” each other, the components can be electrically coupled to each other, with or without other components being electrically coupled and intervening between them. When two components are described as being “directly connected to” or “directly coupled to” each other, the components can be electrically coupled to each other, without other components being electrically coupled between them.

Terms such as “a,” “an,” “the,” and “said” are used to indicate the presence of at least one element or component (e.g., one or, alternatively, more than one), unless particularly identified as one and only one (e.g., single or singular one). The terms “comprise,” “include,” “have,” “contain,” and their variants are open ended and may include or encompass additional elements, components, etc., in addition to the listed elements, components, etc., unless otherwise specified. The terms “first,” “second,” etc. are used only as distinguishing or separating labels, rather than a limitation of a number of the components, unless particularly used as a numerical quantifier.

Although embodiments have been described herein in detail, the descriptions are by way of example. The features of the embodiments described herein are representative and, in alternative embodiments, certain features and elements can be added or omitted. Additionally, modifications to aspects of the embodiments described herein can be made by those skilled in the art without departing from the spirit and scope of the present invention defined in the following claims, the scope of which are to be accorded the broadest interpretation so as to encompass modifications and equivalent structures.

Therefore, the following is claimed:

1. A diode switch, comprising:
a common port, a first port, and a second port;
a first switch arm electrically coupled between the first port and the common port; and
a second switch arm electrically coupled between the second port and the common port, wherein the first switch arm comprises:
a first node and a second node each electrically coupled between and electrically separated from the first port and the common port;
a shunt diode electrically coupled between the first node and ground;
a termination leg electrically coupled between the second node and ground; and
a series diode electrically coupled between the first node and the second node.

2. The diode switch according to claim 1, wherein the diode switch comprises an absorptive switch.

3. The diode switch according to claim 1, further comprising:
a second series diode electrically coupled between the common port and the first node, wherein the diode switch comprises an absorptive switch without a quarter-wavelength transmission line.

4. The diode switch according to claim 1, further comprising a transmission line electrically coupled between the common port and the first node.

5. The diode switch according to claim 1, wherein the termination leg comprises a second shunt diode and a resistor electrically coupled in series between the second node and ground.

6. The diode switch according to claim 1, further comprising:
a first bias node electrically coupled to the first node;
a bias diode electrically coupled between the first bias node and the first node; and
a second bias diode electrically coupled between the second node and the termination leg, wherein the termination leg comprises a second shunt diode and a resistor coupled in series between the second node and ground.

7. The diode switch according to claim 1, wherein the second switch arm comprises:
a third node and a fourth node each electrically coupled between and electrically separated from the second port and the common port;
a second shunt diode electrically coupled between the third node and ground;
a second termination leg electrically coupled between the fourth node and ground; and
a second series diode electrically coupled between the third node and the fourth node.

8. The diode switch according to claim 7, further comprising a third series diode electrically coupled between the common port and the third node.

9. The diode switch according to claim 7, further comprising a transmission line electrically coupled between the common port and the third node.

10. The diode switch according to claim 7, wherein the second termination leg comprises a second shunt diode and a resistor electrically coupled in series between the fourth node and ground.

11. The diode switch according to claim 7, wherein a first intrinsic region thickness of at least one diode in the first switch arm is different than a second intrinsic region thickness of at least one diode in the second switch arm.

12. The diode switch according to claim 1, further comprising:
a third port; and
a third switch arm electrically coupled between the third port and the common port.

13. The diode switch according to claim 1, wherein the second switch arm comprises:
a third node and a fourth node each electrically coupled between and electrically separated from the second port and the common port;
a second shunt diode electrically coupled between the third node and ground;
a second termination leg electrically coupled between the fourth node and ground; and
a transmission line electrically coupled between the third node and the fourth node.

14. A diode switch, comprising:
a common port and a first port; and
a switch arm electrically coupled between the first port and the common port, wherein the switch arm comprises:
a first node and a second node each electrically coupled between and electrically separated from the first port and the common port;
a shunt diode electrically coupled between the first node and ground;
a termination leg electrically coupled between the second node and ground; and
a series diode electrically coupled between the first node and the second node.

15. The diode switch according to claim 14, wherein the diode switch comprises an absorptive switch.

16. The diode switch according to claim 14, further comprising:
a second series diode electrically coupled between the common port and the first node, wherein the diode switch comprises an absorptive switch without a quarter-wavelength transmission line.

17. The diode switch according to claim 14, further comprising a transmission line electrically coupled between the common port and the first node.

18. The diode switch according to claim 14, wherein the termination leg comprises a second shunt diode and a resistor electrically coupled in series between the second node and ground.

19. The diode switch according to claim 14, further comprising:
a first bias node electrically coupled to the first node;
a bias diode electrically coupled between the first bias node and the first node; and
a second bias diode electrically coupled between the second node and the termination leg, wherein the termination leg comprises a second shunt diode and a resistor coupled in series between the second node and ground.

20. The diode switch according to claim 14, further comprising:
a second port; and
a second switch arm electrically coupled between the second port and the common port, wherein the second switch arm comprises:
a third node and a fourth node each electrically coupled between and electrically separated from the second port and the common port;
a second shunt diode electrically coupled between the third node and ground;
a second termination leg electrically coupled between the fourth node and ground; and
a second series diode electrically coupled between the third node and the fourth node.
